(19) United States
(12) Patent Application Publication
(10) Pub. No.: US 2013/0143022 A1
(43) Pub. Date: Jun. 6, 2013

(54) METHOD FOR PRODUCING DIAMOND LAYERS AND DIAMONDS PRODUCED BY THE METHOD

(71) Applicants: Matthias Schreck, Augsburg (DE); Stefan Gsell, Dillingen (DE); Martin Fischer, Augsburg (DE)

(72) Inventors: Matthias Schreck, Augsburg (DE); Stefan Gsell, Dillingen (DE); Martin Fischer, Augsburg (DE)

(73) Assignee: UNIVERSITAET AUGSBURG, Augsburg (DE)

(21) Appl. No.: 13/703,812

(22) PCT Filed: Jun. 16, 2011
(86) PCT No.: PCT/EP2011/002983

§ 371 Date: Feb. 13, 2013

(30) Foreign Application Priority Data
Jun. 16, 2010 (DE) 102010023952.6

(51) Int. Cl. C30B 25/18; C30B 29/04; C30B 25/04

(52) U.S. Cl. CPC C30B 25/18; C30B 25/04; C30B 25/183; C30B 29/04
USPC 428/220; 117/101; 117/95; 428/408; 423/446

(57) ABSTRACT

The present invention relates to a method for producing diamond layers, wherein firstly, in a first growing step, diamond is grown on a growing surface of a off axis or a off-axis heterosubstrate in such a way that a texture width, in particular a polar and/or azimuthal texture width, of a diamond layer produced during the growth decreases with increasing distance from the substrate and then, in a second growing step, diamond is grown in such a way that the texture width of the diamond layer remains substantially constant as the distance from the substrate further increases, and lattice planes of the substrate being inclined by an angle greater than zero with respect to the growing surface.

### PRIORITY INFORMATION

This application is a 371 application of PCT Application No. PCT/EP2011/002983, filed on Jun. 16, 2011 that claims priority to German Application No. 102010023952.6 filed on Jun. 16, 2010, both of which are incorporated herein in their entirety.

### BACKGROUND OF THE INVENTION

The invention relates to a method for producing diamond layers and to diamonds produced using said method, wherein the diamond layers are grown on off-axis. Diamond layers having defined texture widths and high breaking strength can be produced by a suitable choice of the substrate of the growth and/or by a suitable process management. Diamond layers of this type can be used particularly advantageously as neutron monochromators for mechanical, optical and electrical components. They can furthermore also be used as growth substrates for epitaxial functional layers such as nitrides (inter alia AlN, GaN, c-BN).

It is as a rule the goal in the growth of diamond crystals to produce monocrystals of the highest structural quality and with a minimum of chemical impurities or defects. In this respect, a minimal density of structural defects such as dislocations and stacking faults is aimed for.

Heteroepitaxial diamond layers can be produced, for example, in an apparatus and in a method such as are described in DE 10 2007 028 293 B4. A high density of oriented diamond crystals is here first applied to iridium layer wafers. These initially individual diamond crystals having an initial texture width of roughly 1° interconnect in a subsequent growth process and in so doing lose their individual character. The density of dislocations in this respect is relatively high (e.g. 10⁹ cm⁻²) and the texture width reduces as the layer thickness increases (e.g. 0.16° polar and 0.34° azimuthal). A growth of the actual layer is in particular possible using microwave-assisted CVD.

The term of texture width is used within the framework of this invention. It can be understood as follows. In a perfect monocrystal, the network planes (hk1) have the same orientation in space at all points in the crystal, i.e. the network planes (hk1) at two different positions in the crystal are always parallel to one another. This parallelism is no longer present in a real crystal with structural defects such as dislocations. If a mosaic crystal is present, the crystal is composed of individual mosaic blocks which are separated from one another by small angle grain boundaries and are slightly tilted and/or rotated with respect to one another. The invention relates to samples in which one of these two situations or a mixture of the two is present.

The orientation distribution of the network planes can be called the mosaic width or the texture width. The term texture width will be used here which should also apply to the case of a monocrystal in which the orientation distribution of the network planes is e.g. only widened by the presence of dislocations.

The texture width can be measured by means of X-ray diffraction. The monochromatized Kα1 line of a copper pipe at a wavelength λ of 0.15406 nm can e.g. be used for the samples described here. The monochromatization can e.g. take place with a germanium crystal monochromator with 4-fold reflection (Bartels monochromator) using the Ge (220) or optionally the Ge (440) Bragg reflections. With this parallel beam scattering geometry, a germanium analyzer crystal with 2-fold reflection can then, for example, be used at the secondary side.

In the sample growth, the growth surface normally defines a preferred direction with respect to which polar and azimuthal texture widths are distinguished. A network plane family of curves (hk1) can first be selected for both for a measurement and the detector can be set so that it only detects radiation within its acceptance angle which was diffracted by twice the Bragg angle 2Θₕₖ₁. In the measurement of the polar texture width using a rocking curve, a low-indexed network plane family of curves with an intense Bragg reflection is advantageously selected which is disposed parallel to the growth surface or only adopts an angle of a few degrees with the growth surface with off-axial substrates. Subsequently, the sample orientation is then advantageously sought in which the maximum of the intensity for this network plane family of curves occurs. The sample can be rotated about an axis (rocking axis) in small angular steps and the intensity of the reflected X-rays are recorded for the carrying out of the rocking curve measurement. The rocking axis in this respect results from the intersection of the growth surface with the plane for which the intensity maximum was found. The sample is moreover advantageously to be oriented so that the rocking axis stands perpendicular on incident and diffracted X-radiation. The full width half maximum of this curve is called the polar texture width here.

The azimuthal texture width relates to the rotation of the network planes about an axis of rotation perpendicular to the growth surface. In this respect, a network plane family of curves is most favorably selected for the measurement which stands perpendicular or almost perpendicular on the growth surface. The network plane family of curves is then preferably aligned with the reflection of the X-radiation in the detector so that the angles between incident X-radiation and the surface normals as well as diffracted X-radiation and the surface normals are simultaneously as large as possible. In the ideal case, with on-axis samples and the selection of a network plane standing ideally perpendicular to the growth surface, both angles are 90°. On the rotation about the surface normals, the reflected intensity can be recorded as the function of the angle. For a network plane standing perpendicular, the full width half maximum of this curve directly corresponds to the azimuthal texture width (while neglecting the instrumental broadening). A correction of the absolute numerical values can preferably be carried out for highly inclined network planes (>>10°) such as described in Thürer et al., Phys. Rev. Vol. 57 (1998) 15 454.

If only the texture width is spoken of in such a sample, it is the polar and/or azimuthal texture width.

If the growth surface is not known for a sample, texture width is to be understood as the maximum rocking curve width which is measured for any network plane family of curves of the sample.

It has been found that a reduction of the text width in particular takes place with increasing layer thickness on (001) oriented silicon or iridium, in particular, when the growing on process is carried out so that a growth of the diamond along the crystallographic [100] direction is preferred (M. Schreck, A. Schury, F. Hörmann, H. Roll, and B. Stritzker: J. Appl. Phys. 91 (2002) 676). It was in particular observed in this respect that in the case of silicon only the texture width of the polar orientation distribution was reduced, while with iridium the polar and azimuthal orientation distribution was reduced. The setting of the defined mosaic widths is not directly controllable according to the prior art. This in particular applies to homogeneous mosaic widths over thick films of more than a hundred micrometers.

### SUMMARY OF THE INVENTION

Diamond crystals with an adjustable texture width provide a variety of application possibilities, in particular when they can be produced over a large area. Crystals can thus be used with a small texture width and a low dislocation density for e.g. electronic components. With small texture widths, the crystals can also be used as monochromators for X-radiation, in particular in synchrotron radiation sources. It would furthermore also open up the possibility of producing mechanical components such as cutting edges, dressing tools, draw plates, cutting edges for precision working, medical scalpels and similar with epitaxial crystals, in particular from CVD synthesis. This would have the advantage over polycrystalline diamonds of a homogeneous crystal structure with homogeneous wear, which would e.g. make possible a final machining of components with optical quality of the surfaces. Diamond crystals are also particularly advantageous for a monochromatization of neutron rays, in particular with wavelengths from 0.05 to 0.3 nm, in particular in the range of polar texture widths between 0.2° and 0.8°. In this respect, the mosaic widths desired for the neutron monochromators can also be achieved by stacking crystals of smaller mosaic width which are slightly tilted angle-wise. Specifically, a mosaic width of e.g. 0.3° could be realized by stacking a plurality of mosaic crystals with single rocking curves widths of e.g. 0.15° over one another which are mutually tilted by around 0.1°. It is therefore the object of the present invention to provide a method by which diamond crystals having a defined texture width can be produced on large surfaces, preferably larger than 1 cm², and having large thicknesses, preferably larger than 10 μm.

The object is achieved by the method in accordance with claim 1, the method in accordance with claim 2, the diamond crystals in accordance with claims 15 to 18 and 22, the neutron monochromator in accordance with claim 24 and the use in accordance with claim 25. The respective dependent claims set forth advantageous further developments of the methods in accordance with the invention and of the diamond crystals in accordance with the invention.

In accordance with the invention, diamond is deposited onto a surface of a substrate, with the substrate having an off-axis orientation.

In this application an (hk1) off-axis substrate, where h, k and I are the so-called Miller indices, is understood as a substrate whose crystal lattice planes (hk1) are inclined by an angle greater than zero, the so-called off-axis angle, with respect to the growth surface. In the case of an off-axis substrate, those crystal lattice planes which extended parallel to the surface on which the diamond was deposited with conventional epitaxy are therefore inclined by the angle with respect to the surface. In the off-axis case, the corresponding lattice planes are therefore not exactly parallel to the surface onto which growth takes place, but rather only “substantially parallel” to this surface, namely inclined by the angle.

In accordance with the invention, the diamond is optionally deposited heteroepitxially after nucleation, which means, on the one hand, that the production of the diamond crystal takes place expitaxially and, on the other hand, that a material of the substrate does not compose diamond.

A substrate is particularly preferred which has iridium with an (001) off-axis orientation or a (111) off-axis orientation on a, preferably oxide, buffer layer, preferably yttria stabilized zirconia (YSZ), on a silicon monocrystal, that is e.g. Ir/YSZ/Si (001) or Ir/YSZ/Si (111). Such a substrate has a very good thermal adaptation to diamond. The iridium layer is particularly well oriented in such a substrate layer system and is in particular better oriented than the oxide buffer layer. In addition, other oxides are also suitable as the buffer layer, such as SrTiO₃, CeO₂, MgO, Al₂₀O₃, TiO₂, or also buffer layers which consist of or comprise TiN and SiC. In the case of Ir/YSZ/Si, the YSZ layer is first applied to the Si (001) off-axis crystals or Si (111) off-axis crystals, e.g. by sputtering, but preferably by means of pulsed laser ablation, at a substrate temperature of, for example, 720° C. and an oxygen pressure of 5×10⁻⁴ mbar. The first 2 nm are in this respect deposited under high vacuum conditions. The concentration of yttria (Y₂O₃) in zirconia (ZrO₂) can in this respect vary over a wide range, e.g. amount to ≦2.5% or 8% or ≧12%. The iridium layer with a thickness of, for example, 150 nm is preferably grown on by means of electron beam evaporation, preferably a two-step process, at a temperature of, for example, 650° C. The first step for the first 20 nm in this respect takes place at a growth rate of, for example, 0.004 nm/s. The following epitaxial nucleation of diamond on the Ir/YSZ/Si (001) off-axis substrates or Ir/YSZ/Si (111) off-axis substrates takes place preferably using the method of DV voltage assisted nucleation such as in described in DE 10 2007 028 293 B4.

Diamond can be heteroepitaxially deposited on a monocrystalline or quasi-monocrystalline iridium layer with a uniquely good orientation. It moreover bonds very well on the iridium. The total layer system furthermore has an extremely high thermal stability, which is documented by day-long deposition processes in the microwave plasma at temperatures of around 1000° C.

The texture width, that is the polar and/or the azimuthal texture width, of the deposited diamond is preferably set directly. Setting the texture width can in this respect mean minimization of the texture width or setting a defined value, which is as constant as possible, over a wide region of the layer thickness. The diamond is in this respect preferably deposited by means of chemical vapor deposition (CVD), and particularly preferably by means of microwave-assisted chemical vapor deposition such as is described in DE 10 2007 028 293 B4.

It was now recognized in accordance with the invention that in this respect the texture width of the deposited diamond can be set via a nitrogen concentration in a gas used for the chemical vapor deposition. A continuous improvement of an (001) texture can e.g. be prevented by means of high nitrogen concentrations without producing a transition to nanocrystalline layers. If the texture width should be minimized, the nitrogen concentration can be selected as small or as equal to zero. Unlike the normal on-axis growth, in the off-axis growth described in the following, no nitrogen at all is required to stabilize (001) oriented growth and to minimize the mosaic distribution in so doing. With high nitrogen concentrations in contrast, layers with a larger texture width can be produced in a defined form. The higher the nitrogen concentration is set, the larger the texture width of the deposited diamond becomes. In the case of non-minimal texture width, nitrogen concentrations ≧400 ppm, particularly preferably ≧800 ppm, further preferably ≧1000 ppm, further preferably ≧1200 ppm, further preferably 1500 ppm and/or ≦20000 ppm, preferably ≦10000 ppm, particularly preferably ≦5000 ppm, are particularly preferred.

The method in accordance with the invention can advantageously be carried out in two steps to achieve a diamond having a texture width defined over a specific layer thickness, in particular a defined polar texture width. In this respect, diamond is first grown onto the hetero substrate in a first growth step so that the texture width of the diamond being added decreases with an increasing distance from the substrate. As the thickness of the diamond increases, the texture width of the diamond being added therefore becomes smaller. In a second growth step, diamond is then grown on so that the texture width of the diamond layer remains substantially constant with a further increasing distance from the substrate. In the second growth step, the texture width of the diamond being added is therefore substantially constant. The setting of the texture width to the constant value in this respect preferably takes place via the above-described setting of the nitrogen concentration in the chemical vapor deposition.

The surfaces of the substrate on which the diamond is deposited are in this respect preferably (001) off-axis surfaces and (111) off-axis surfaces in which the orientation of the growth surface differs by an angle of some degrees from the crystallographic (001) surface or (111) surface.

The angle of the off-axis orientation, that is the above-named angle by which the crystal planes are inclined with respect to the surface, is preferably ≧2°, particularly preferably ≧4° and/or ≦15°, preferably ≦10° and/or preferably ≦8°.

Unless a minimization of the texture width is aimed for, the texture width of the deposited diamond, in particular the polar texture width, which is set, in particular in the second growth step of the above-descried advantageous method, is preferably ≧0.1°, particularly preferably ≧0.2°, further preferably ≧0.3°, further preferably ≧0.4° and/or ≦2°, preferably ≦1°, particularly preferably ≦0.8°, further preferably ≦0.6°, further preferably ≦0.5°. Texture widths between 0.2° and 1° are advantageous for neutron monochromators. It is in particular important here that the texture width can be set directly and can be kept constant over the thickness.

A minimization of the polar and/or azimuthal texture width can also be aimed for which results in high-end monocrystals with a few hundreds of a degree of texture width. In this case, the two texture widths are preferably ≦0.1°, particularly preferably ≦0.05°, further preferably ≦0.02°. Such small texture widths for heteroepitaxial diamond layers on large surfaces of several square centimeters are not described in the prior art and are only made possible by the method in accordance with the invention.

The composition of the gas phase, and in particular also the addition of nitrogen, influences the growth forms of individual diamond crystals and can in this respect be used to suppress twins or non-epitaxial crystallites on (001) surfaces. Contrary conditions, i.e. as little nitrogen and methane in the gas phase as possible, are required on (111) surfaces to allow a monocrystalline growth without polycrystalline inclusions. It is now possible to ignore these restrictions by using off-axis substrates, i.e. minimal texture widths can be achieved with a nitrogen-free gas phase without twins or non-epitaxial crystallites being created, whereas very high doses of nitrogen can be used to produce and to stabilize higher texture widths without the risk of the transition into the nanocrystalline growth.

The described off-axis growing on allows diamond layers to be produced with a larger layer thickness, in particular preferably ≧0.5 mm, particularly preferably ≧1 mm, further preferably ≧2 mm, further preferably ≧4 mm. At the same time, the diamond layer can be grown on with a large surface which is ≧4 cm², preferably ≧10 cm², particularly preferably ≧30 cm², further preferably ≧50 cm², further preferably ≧70 cm². Diamond layers produced using the method in accordance with the invention moreover have a very high breaking strength which is ≧1 GPa, preferably ≧2 GPa, particularly preferably ≧2.8 GPa, further preferably ≧3 GPa, further preferably ≧3.5 GPa, further preferably ≧3.9 GPa.

It is possible after the completion of the deposition of the diamond to remove, for example to grind off, the substrate and preferably also that diamond layer produced in the above-described first growth step so that a diamond crystal with a homogeneous texture width is produced as the produced diamond crystal.

The production of a diamond crystal using the method in accordance with the invention can be recognized at the fully produced diamond crystal, even if the substrate or parts of the diamond crystal were removed. The production in accordance with the method in accordance with the invention is manifested in that dislocation lines in the diamond crystal are inclined by an inclination angle with respect to the [001] direction in the case of growth on (001) off-axis substrates and with respect to the [111] direction with growth on (111) off-axis substrates. With diamond layers produced using chemical vapor deposition on (001) on-axis substrates, the dislocation lines as a rule extend close to the [001] direction, but can have an inclination angle of some degrees. The dislocation lines usually have a much stronger inclination, e.g. up to 35°, on (111) on-axis substrates under analog conditions. However, in diamond crystals produced in accordance with the standard technology, there are no differences between the inclination in the direction [hk0] and the opposite direction [-h-k0] with growth in the direction [001]. If therefore a main area of the orientation distribution of the dislocation lines, that is an average angle and an average direction of the dislocation lines with respect to the [001] direction, is determined, it is found with diamond crystals produced in accordance with the prior art that the direction of the main area substantially coincides with the [001] direction. With diamond crystals produced in accordance with the method in accordance with the invention, in contrast, it is found that the average value or main area of the angle distribution of the dislocation lines has an angle with respect to the [001] direction which may be 8°, preferably ≧10°, preferably ≧15° and particularly preferably ≧20°. The direction of inclination of the direction of the main area (i.e. in the case of (001) off-axis substrates, the projection of the direction of the main area in the (001) plane) in this respect corresponds to the off-axis direction. It therefore stands perpendicular to that axis of rotation which moves the (001) or (111) network plane into the surface plane by rotation about the off-axis angle.

A diamond crystal whose dislocation lines have a preferred orientation which does not coincide either with the <001> or the <111> crystal direction is therefore in accordance with the invention.

A diamond crystal produced using the method in accordance with the invention can particularly advantageously be used as a neutron monochromator. Neutron monochromators are the central optical elements in neutron research reactors. Due to the comparatively small brilliance (neutron influence) of such reactors, mosaic crystals are used whose texture width is adapted to a beam divergence of the neutron beam. It has been found that diamond is a very well-suited material for neutron monochromators. The values theoretically expected for diamond with respect to reflectivity surpass the reflectivities of the materials used as standard such as germanium, copper or silicon by up to a factor of 4 for hot neutrons. In accordance with the invention, as described above, a diamond crystal having a defined texture width can be produced such as is necessary for neutron monochromators.

It is particularly preferred if a breaking strength of the diamond crystal produced using the method in accordance with the invention is further increased. For this purpose, subsequent to the diamond layers applied in the above-described method, a further diamond layer can be epitaxially grown on which is grown on so that it is subjected to compressive stress with respect to the previously grown on diamond layer. For this purpose, the diamond layer subjected to compressive stress is in particular grown on with chemical vapor deposition preferably at a lower temperature than the previously grown on layer, preferably at a temperature ≦900° C. for (001) off-axis layers and ≦700° C. for (111) off-axis layers. Further preferably, the layer subjected to compressive stress is grown on at the named temperatures and at a higher pressure than the previously grown on layer, preferably at a pressure ≧100 mbar, particularly preferably ≧150 mbar, particularly preferably ≧200 mbar, and/or ≦500 mbar, preferably ≦400 bar.

The structure of a layer subjected to compressive stress in accordance with the invention does not require the ex situ diffusion of foreign elements as described in other inventions on diamond. The epitaxial orientation and the crystalline structure are also maintained. The transition into a region of critical stresses at higher strains takes place by the compressive stresses on a mechanical strain of the layer systems, i.e. the breaking strength of the component increases.

It is possible in the method in accordance with the invention due to the off-axis growth and the direct setting capability of the texture widths to set dislocation densities and texture widths by a selective process control and in so doing to generate compressive stresses of several gigapascals, with the epitaxial crystal growth being maintained. Dislocation densities can lie, for example, between 10⁷ and 10¹² cm⁻². Texture widths can lie e.g. between 0.05° and 1°. Described layers subjected to compressive stresses can be applied to one or both sides of the diamond crystal. The diamond crystal can in this respect be stripped off from the substrate or still be arranged on the substrate.

In a further embodiment, at least one mask is arranged on the substrate or on the already deposited diamond before or during the growing on of the diamond so that the mask extends parallel to the substrate or to that surface on which deposition is taking place. In this respect, the mask has at least one opening through which further diamond can be deposited on the already deposited diamond or on the substrate.

Further diamond is then deposited over the mask for so long that a closed diamond layer results over the mask by homoepitaxial lateral growth of the diamond. The mask is preferably a strip mask whose strips extend perpendicular to the off-axis direction. The strips therefore preferably extend parallel to that axis of rotation about which the surface is tilted with respect to the corresponding (001) or (111) lattice planes. A filling factor, that is a ratio of a width of the openings, that is their extent perpendicular to the longitudinal direction, to a spacing of the same margin, e.g. of the left margin, of two adjacent openings to one another is ≦05, preferably ≦0.2, further preferably ≦0.1, further preferably ≦0.05, further preferably ≦0.02.

The width of the opening a will preferably lie at 1 to 5 μm for the manufacture of layers with a minimal dislocation density and mosaic distribution and the filling factor will preferably lie at 0.01 to 02; with layers with a deliberately large mosaic distribution, the opening is advantageously at 5 to 20 μm and the filling factor at 0.2 to 0.5.

The mask can in this respect preferably comprise or consist of one or more substances selected from SiO₂, Ti, Rh, Pt, Cu, Ni and/or iridium. It can moreover preferably have a thickness of ≧10 nm, particularly preferably ≧50 nm and/or ≦300 nm, preferably ≦200 nm.

Epitaxial lateral overgrowth (ELO) can be realized using such a mask. Dislocations through the applied mask are stopped in this respect. Only dislocations which impact the open regions of the mask, that is the openings, continue into the layer disposed thereabove. The reduction of the dislocation density is as a rule accompanied by a tilting of the network planes in specific regions (called wings) of the overgrowing layer, which is expressed inter alia in a splitting of the rocking curve (called wing tilt). In accordance with the invention, defined texture widths such as are required e.g. for neutron monochromators can be produced by the use of such masks, that is e.g. 0.2° to 1°. Since, as described above, deposition is carried out on an off-axis substrate, the symmetrical splitting of the rocking curve with two secondary maxima becomes an asymmetrical splitting with substantially only one secondary maximum, which substantially simplifies the setting of defined texture widths.

The masks can moreover also be used to produce diamond crystals with a sharp texture width and a low dislocation density. As a rule, the filling factors in the described ELO process of commercial semiconductor materials are limited by economically meaningful layer thicknesses. In usual diamond growth processes, layer thicknesses of some hundred micrometers can be realized as standard. Work can therefore be performed with very small filling factors of <0.1 and a closed structure can ultimately still be obtained. The filling factor is in this respect the ratio of width of the opening to a spacing of corresponding margins of two adjacent openings, that is to the spacing of the margins of the adjacent openings disposed in the same direction. A high reduction of dislocations can hereby be achieved. The wing tilt is reduced to one direction by the use of the method in accordance with the invention and in particular by growing on off-axis substrates, which means that the rocking curve only has one secondary maximum or that one of the two secondary maxima of the rocking curve is much larger than the other maximum. The texture width can be further reduced subsequently using the existing growth conditions as described above. In this manner, a crystal with a sharp texture width and a small dislocation density is obtained.

### DETAILED DESCRIPTION OF THE ILLUSTRATED EMBODIMENTS

The invention will be explained in the following with reference to some Figures.

There is shown

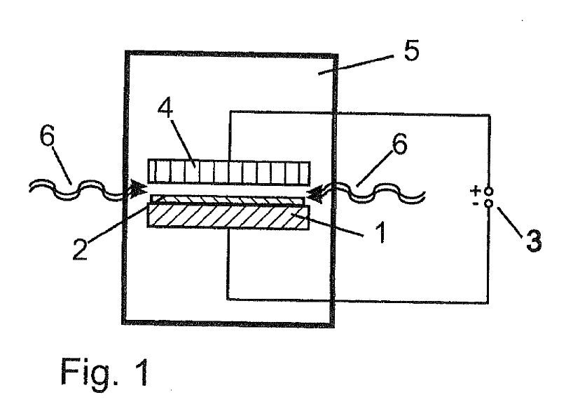

FIG. 1 a plasma reactor in which the nucleation of the diamond layer in accordance with the invention can be carried out;

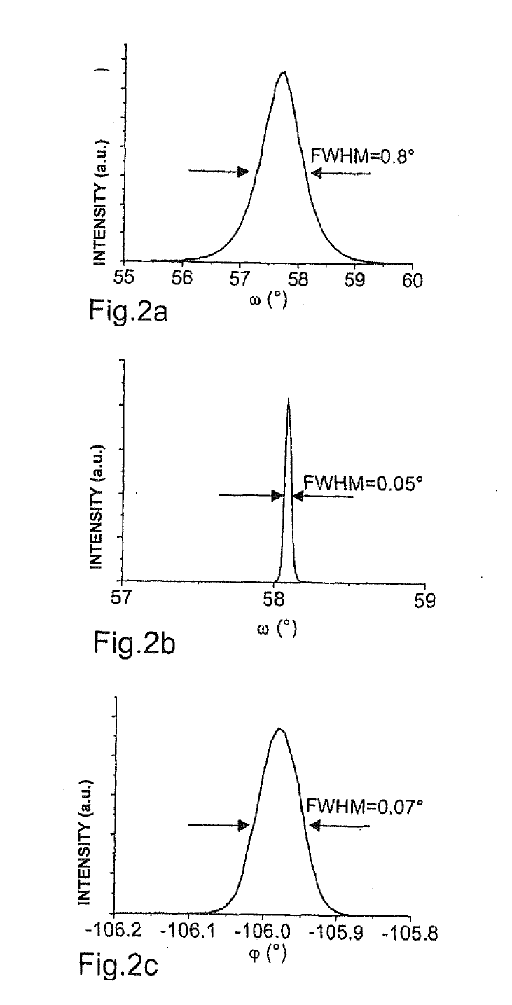

FIG. 2a a rocking curve of a diamond layer produced with a high nitrogen concentration;

FIG. 2b a rocking curve of a diamond layer produced without nitrogen;

FIG. 2c an azimuthal scan of the same diamond layer produced without nitrogen;

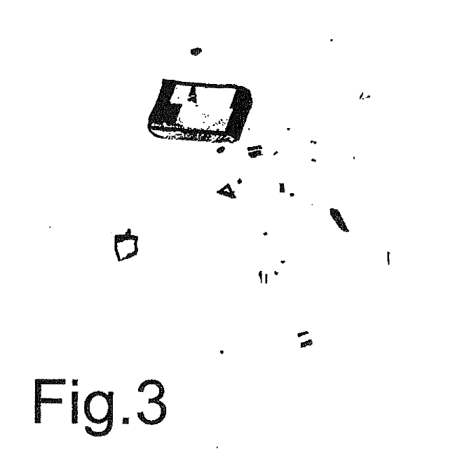

FIG. 3 an example of a diamond layer grown on on-axis;

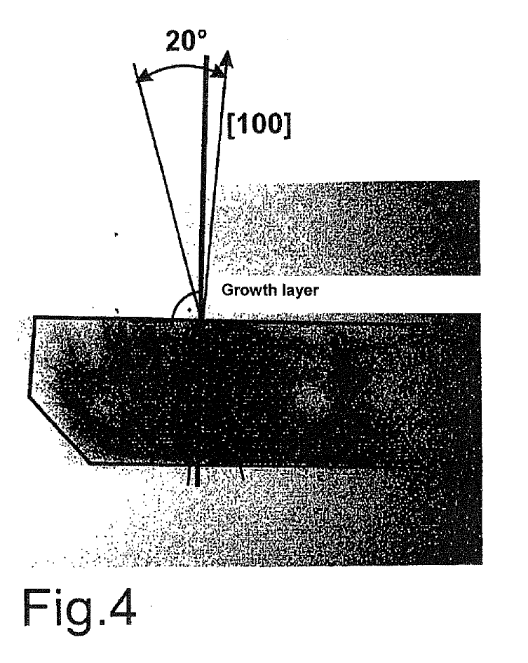

FIG. 4 dislocation lines in a diamond crystal produced in a method in accordance with the invention;

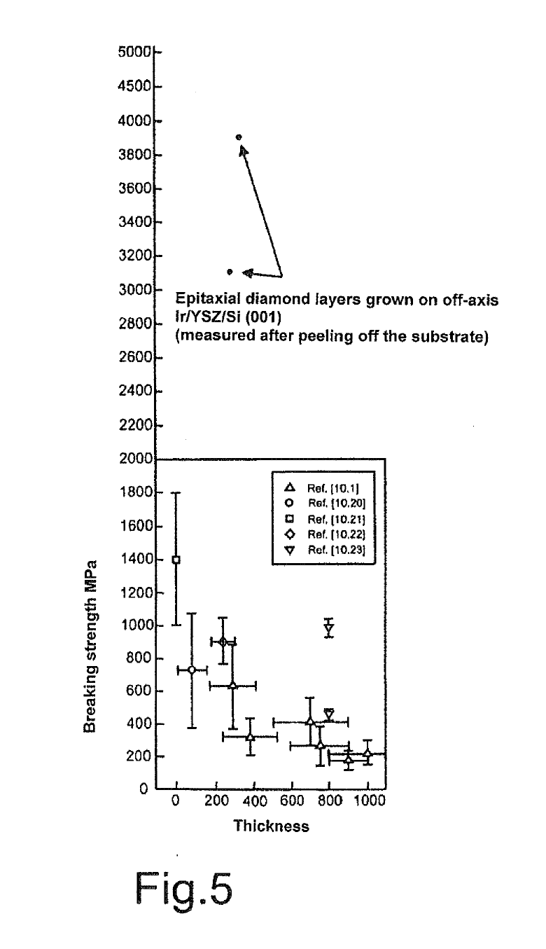

FIG. 5 breaking strengths of diamond crystals produced in accordance with the present method in comparison with breaking strengths of polycrystalline layers;

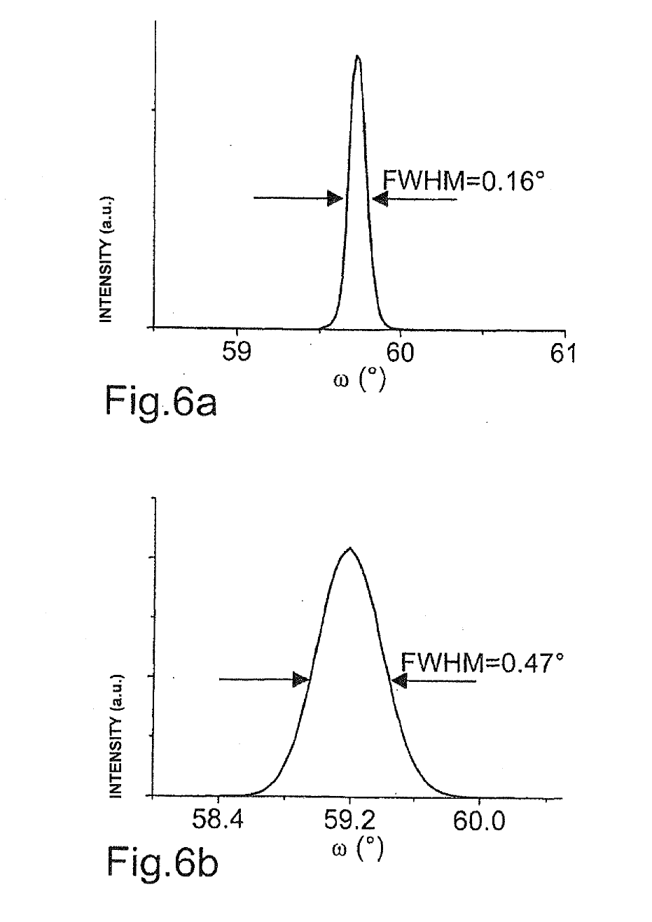

FIG. 6 rocking curves for diamond crystals produced with the method in accordance with the invention with different nitrogen concentrations which can be used for neutron monochromators;

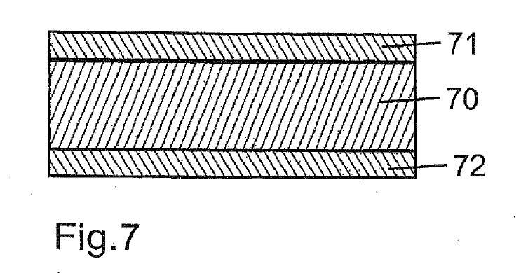

FIG. 7 a schematic representation of a diamond crystal with layers subjected to compressive stresses;

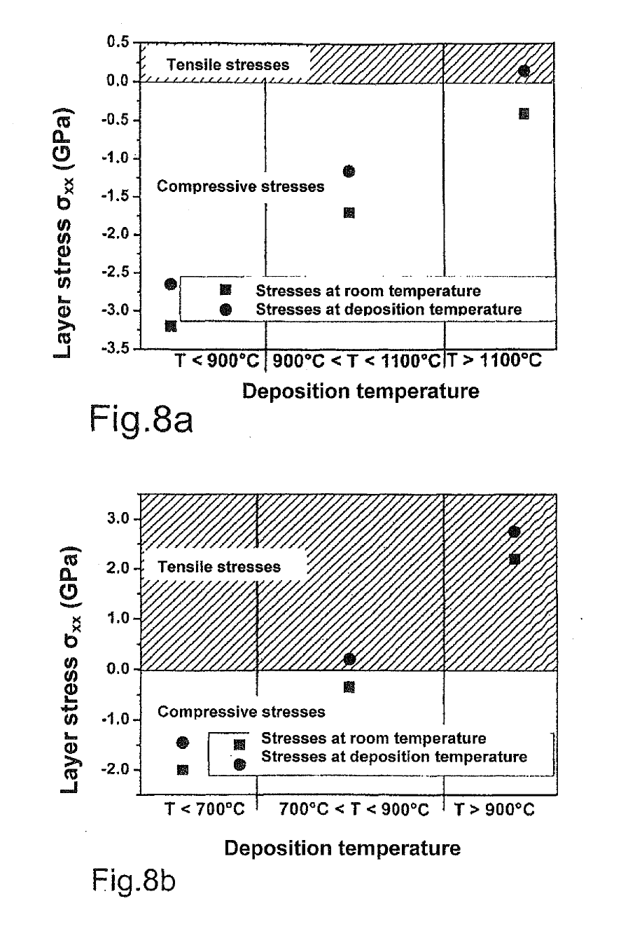

FIG. 8 biaxial stress states σₓₓ adjustable by variation of the substrate temperature for growth on (FIG. 8a) Ir/YSZ/Si(001)4° off-axis substrates or (FIG. 8b) Ir/YSZ/Si (111)4°-off-axis substrates;

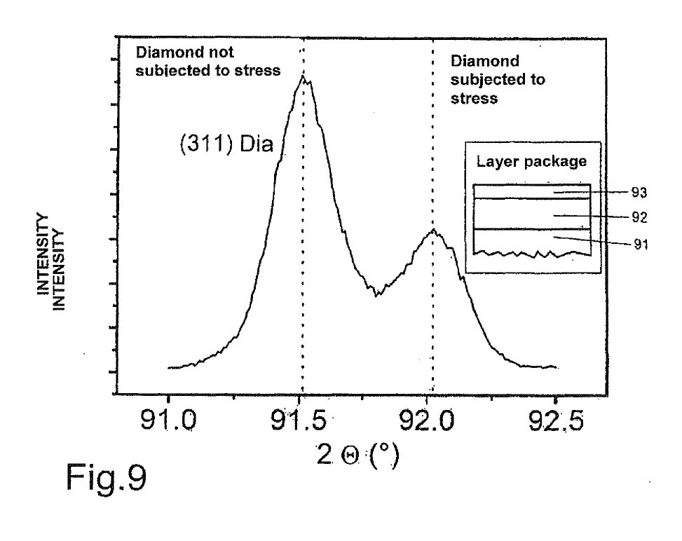

FIG. 9 an example for a diamond layer subjected to high compressive stress on a diamond layer almost free from compressive stress;

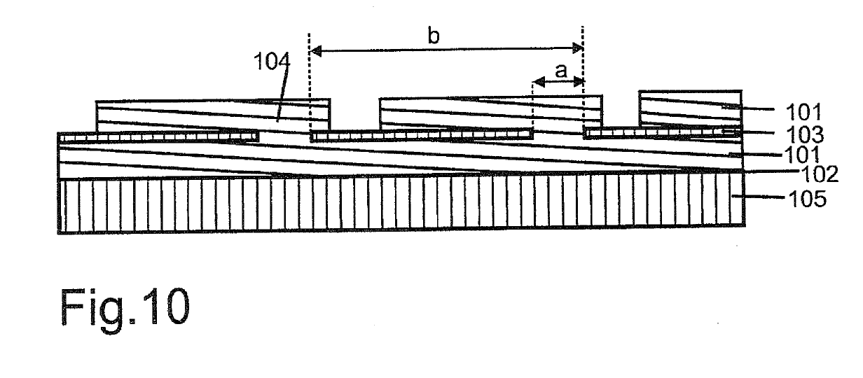

FIG. 10 a section through a diamond crystal arranged on a substrate with a mask via which diamond is deposited; and

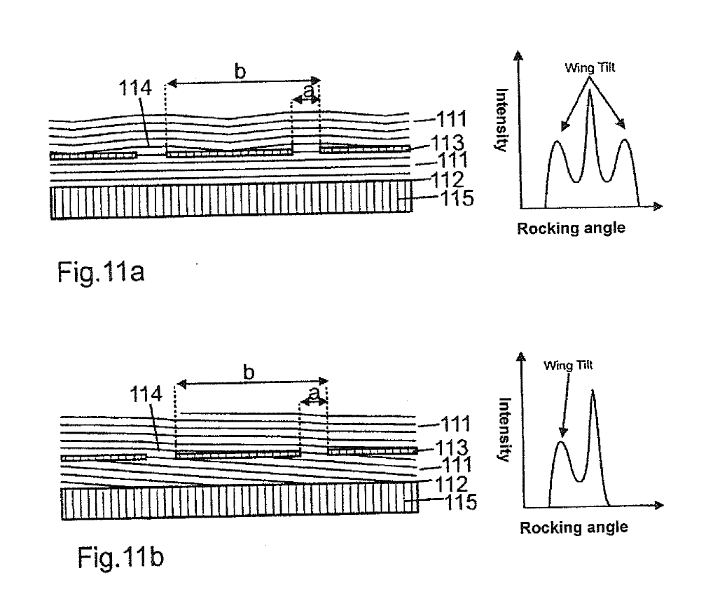

FIG. 11 diamond deposited via masks with tilted network planes.

A microwave plasma source “Cyrannus 1-6” of the company Iplas having a microwave frequency of 2.45 GHz and a power of 6 kW was used for the growth of the diamond samples described in the following.

The X-ray diffraction measurements were carried out using a high-resolution diffraction meter XRD 3003 PTS-HR (Seifert) with parallel beam geometry. The primary beam optics comprised a parabolic X-ray mirror followed by a fourfold Ge (220) Bartels type monochromator for producing a pure Cu Kα1 beam. A further parabolic X-ray mirror was located before the detector on the secondary side.

FIG. 1 shows a plasma reactor with which a diamond nucleation step of the method in accordance with the invention can be carried out. The plasma reactor has a substrate holder 1 on which a substrate 2 can be arranged. The substrate holder 1 is heatable and is connected to a negative pole of a voltage source 3 so that it forms a cathode. The substrate holder 1 is formed areally in this respect. An areally formed anode 4 with a surface parallel to the substrate holder 1 is arranged in a spacing of around 1 cm above the substrate holder 1. The anode 4 is electrically conductively connected to a positive pole of the voltage source 3.

The substrate 2 can be arranged on the substrate holder 1. The anode 4, substrate holder 1 and substrate 2 are arranged in a vacuum chamber 5 which can, for example, be a quartz glass cylinder 5. Microwaves are radiated in between the anode 4 and the substrate 2 and a plasma is ignited so that process conditions arise which allow a chemical vapor deposition of diamond. With a small spacing of anode and substrate (<1 cm), the epitaxial nucleation of diamond on iridium can be achieved over large areas by an additional DC voltage at anode and cathode. The method of this DC voltage-assisted nucleation is described in detail in DE 10 2007 028 293 B4. After the nucleation step, the voltage is switched off, the spacing is increased and subsequently the diamond layer is grown thick in accordance with the invention. The growth steps can also be carried out in other diamond CVD plants, preferably in microwave plasma plants.

FIG. 2a shows a dia (004) X-ray rocking curve of a sample on a 4° off-axis Ir/YSZ/Si (001) substrate. The off-axis angle of 4° is in this respect the angle between the surface of the substrate on which growth takes place and the crystallographic (001) plane The diamond crystal whose X-ray rocking curve is shown in FIG. 2a, was produced using hetroepitaxial diamond nucleation in a two-step growth process, with diamond being grown on in a first step whose texture width decreases with an increasing spacing from the substrate and with diamond being applied in a second step with a substantially constant texture width. The constant texture width was in this respect set via a comparatively high nitrogen concentration of 15,000 ppm N₂ in the gas phase. The remaining process parameters were a gas pressure of 200 mbar, 10% methane in hydrogen, a substrate temperature of 1100° C. and a microwave power of 3500 W. The layer thickness of the crystal here amounted to 900 μm. It can be recognized that the rocking curve full width half maximum, that is the polar texture width, of the crystal is 0.8°.

FIG. 2b shows a dia (004) X-ray rocking curve of a diamond crystal sample which was deposited on a 4° off axis Ir/YSZ/Si (001) substrate, with a minimal texture width being set by the growth without nitrogen in the gas phase. The remaining process parameters were a gas pressure of 160 mbar, 8% methane in hydrogen, a substrate temperature of 1000° C. and a microwave power of 3000 W. The layer thickness here was 1600 μm. It can be recognized that the rocking curve full width half maximum, that is the polar texture width, of the crystal is 0.05°.

FIG. 2c shows an azimuthal scan of the diamond (300) reflection with a full width half maximum of 0.07° for the same layer as in FIG. 2b.

FIG. 3 shows a diamond crystal on a substrate which was produced in accordance with the prior art. In this respect, growth took place for 30 minutes on an Ir/YSZ/Si (001) on-axis substrate, with a nitrogen concentration of 15,000 ppm N₂ being set in the gas phase. It can be recognized that the crystal is fragmented. A great advantage of the present invention with respect to the prior art is disclosed herein since the invention makes it possible to deposit diamond crystals on substrates under conditions which would not result in stable layers in accordance with the prior art.

Only since deposition is off-axis in accordance with the invention can a diamond layer with such high texture width be produced as stable while adding nitrogen.

FIG. 4 shows a (−220) X-ray topographic photo (in transmission, Laue technique) in cross-section of a diamond layer of 3 mm thickness which was deposited using CVD in a method in accordance with the invention. In this respect, deposition was on an Ir/YSZ/Si (001) 4° off-axis substrate, with the process conditions set for FIG. 2b being present. The off-axis direction of the sample was [1-10], i.e. the axis of rotation which moves the (001) plane into the surface was [110]. A 1 mm thick cross-sectional slice was cut out of this sample by means of laser cutting for the X-ray topographic photograph using polychromatic X-ray radiation at a synchrotron source. The cut surface is spanned by the vectors [001] and [1-10]. Dislocation lines of the diamond crystal can be recognized as dark shading in FIG. 4. The dark shading, that is the dislocation lines, in this respect have a preferred direction. This preferred direction is inclined by around 20° in the example shown with respect to the crystallographic [001] direction. The method in accordance with the invention for producing diamond crystals peeled off in the finished layers and possibly also from other layers, in particular from the substrate, can be recognized and demonstrated using these directed dislocation lines. With growth on (111) off-axis substrates, an inclination angle would accordingly result with respect to the [111] direction.

FIG. 5 shows breaking strengths of off-axis grown diamond layers produced using the method in accordance with the invention and produced using CVD with a nitrogen concentration of 400 ppm N₂ in the gas phase. In the lower region of the Figure, within the box, typical breaking strengths of polycrystalline layers are given which were taken from C. Wild, “CVD diamond for optical windows”, in “Low-pressure Synthetic Diamond”, Spinger, 1998. The Figure shows that the breaking strength of polycrystalline diamond layers falls dramatically with respect to high layer thicknesses. In the upper region, breaking strengths of two diamond layers of different thicknesses are applied which were produced using the method in accordance with the invention. The breaking strengths were determined for thicknesses of around 300 μm thickness after peeling off the substrate at laser-cut 0.5 mm×11 mm test pieces using 3-point bending strength measuring. Deposition was here also off-axis on an Ir/YSZ/Si (001) substrate. It can be recognized that the breaking strength of the diamond layers produced in accordance with the invention lies at 3100 MPa or 3900 MPa. That is, it is substantially larger than with conventional polycrystalline diamond layers of comparable layer thicknesses.

FIG. 6 shows dia (004) X-ray rocking curves of samples which were grown on 4° off-axis Ir/YSZ/Si (001) substrates. In this respect, the first growth step was aborted at around 0.17° for the texture reduction for the sample shown in FIG. 6a and growth was then continued with 1000 ppm N₂ in the gas phase. With the sample shown in FIG. 6b, in contrast, the first process step was ended as early as 0.5° and growth in the second step was at 10,000 ppm N₂. In both cases, a substantial constant full width half maximum was set via the above-described two-step growth process by switching over with a defined texture width and a selection of the nitrogen concentration in the following growing over hundreds of micrometers.

The layer thickness of the sample shown in the left part image is 1000 μm and that of the sample shown in the right part image 650 μm. The diamond layers were here selectively produced with a texture width of around 0.16° in the left part image and directly with a texture width of 0.47° in the right part image using the above-described method. The neutron reflectivities measured at these layers amount to 34% for the left part image and 11% for the right part image. These values are already at around 70% of the theoretical reflectivities expected in the respective layer thicknesses. In particular the left sample has twice as high a neutron reflectivity at a layer thickness of only 1 mm than the germanium used as standard at this wavelength (1 Ang) at a layer thickness of 12 mm on (Ge (111) reflection: 18% reflectivity at 12 mm layer thickness and a polar texture width of 0.3°).

FIG. 7 schematically shows a diamond crystal 70 on whose upper side and lower side diamond layers 71 and 72 subjected to compressive stresses are applied. In this respect a epitaxial layer 71 subjected to compressive stress is arranged on the upper side and an epitaxial layer 72 subjected to compressive stress on the lower side on a quasi-monocrystalline diamond layer 70 produced using the method in accordance with the invention with a texture width between 0.05° and 1°. The compressive stress can in particular be effected by deposition of the layers 71 and 72 subjected to compressive stresses at high pressures in the CVD gas phase and at comparatively lower temperatures.

FIG. 8 shows the direct setting of stresses in heteroepitaxial growth of diamond on Ir/YSZ/Si (001) 4° off axis (FIG. 8a) and Ir/YSZ/Si (111) 4° off-axis (FIG. 8b) by selection of the temperature with otherwise equal process conditions. The process conditions were a process gas pressure of 200 mbar, 7-10% methane in hydrogen and a microwave power of 3500 W. It can be recognized for the case in FIG. 8a that the compressive stresses increase with a decreasing temperature. For the case in FIG. 8b, a compressive stress of around −2 GPa can be set at a temperature of less than 700° C., whereas tensile stresses of up to 2 GPa result at temperatures of >900° C.

In addition to the internal stresses measured at room temperature using X-ray diffraction, the stresses were also given which result purely mathematically at the deposition temperature in that the different thermal coefficients of expansion of the diamond layer and the substrate are taken into account.

FIG. 9 shows an embodiment for a diamond layer 93 subjected to high compressive stress on a diamond layer 92 almost free from compressive stress. For this purpose, a heteroepitaxial diamond layer 92 of a 20 μm thickness was first grown on an Ir/YSZ/Si (001) 4° off axis substrate 91. The process conditions were a gas pressure of 50 mbar, 2200 W microwave power, 2% methane in hydrogen, 150 ppm nitrogen, a substrate temperature of 850° C. for 20 hours. Subsequently, a layer subjected to compressive stress was grown at a pressure of 220 mbar, 3500 W microwave power with 10% methane in hydrogen at a substrate temperature of around 750° C. for 2 h. The layer subjected to compressive stress grew homoepitaxially in this process on the layer not subjected to stress and had a thickness of 8 μm. The Figure show a theta-2-theta X-ray diffraction measurement of the diamond (311) reflection taken at a polar angle of around 72° using pure Cu Kα1 radiation. The reflection of the layer not subjected to stress is at a value of 91.5°. The reflection of the layer subjected to stress is in contrast displaced by 0.5° to a larger 2-theta angle. An opposite displacement of −0.2° is obtained for the diamond (004) reflection at 2 theta 119.5° and a polar angle of around 4°. A compression κₓₓ in the plane of 0.48% results from this, which corresponds to a compressive stress σₓₓ of −5.7 GPa in the layer plane with a biaxial stress state. Depth-dependent micro-raman measurements document the order of the diamond layer subjected to compressive stress on the diamond layer not subjected to compressive stress and confirm the stress values.

FIG. 10 shows off-axis deposited diamond layers on a substrate 105, with a mask 103 being arranged with a parallel plane to the substrate 105 during the deposition. Since deposition on the substrate 105 is off-axis, crystal lattice planes 101 are inclined by an angle with respect to the surface 102 of the substrate 105. First, therefore, diamond is now deposited on the surface 102 of the substrate 105; then, after depositing diamond in a specific thickness, the diamond growth process is interrupted, the mask 103 is subsequently applied over the already deposited diamond and then further diamond is deposited which is applied within the openings 104 of the mask 103 onto the diamond layers laying beneath the mask and in addition is deposited over the mask 103 by homoepitaxial lateral growth. The thickness of the diamond layer before the application of the mask is selected to be so high for the manufacture of layers with minimal texture width that a plurality of dislocations were already grown over and the texture width has already considerably reduced. i.e. the thickness can be ≧100 μm, preferably ≧500μm, preferably ≧1 mm, ≧2 mm.

A filling factor of the mask 103 is given as the ratio of the width of the openings a to a spacing of two margins b bounding adjacent openings in the same direction. The filling factor can lie, for example, between 0.01 and 0.5. The width of the opening a will lie at 1 to 5 μm for the manufacture of layers with a minimal dislocation density and mosaic distribution and the filling factor will lie at 0.01 to 0.2; with layers with a deliberately large mosaic distribution, the opening is advantageously at 5 to 20 μm and the filling factor at 0.2 to 0.5.

FIG. 11 shows the effect of the wing tilt in the epitaxial lateral overgrowth (ELO) of masks in comparison for on-axis (a) and off-axis (b) grown on diamond. In this respect, a mask 113 which has openings 114 is arranged over diamond layers which were continuously produced. The lattice planes 111 of the diamond beneath the mask 113 extend in parallel to the substrate and to the surface in the case of on-axis grown on diamond and is inclined by an angle for off axis grown on diamond. Above the openings, the lattice planes 111 likewise extend substantially parallel to the lattice planes of the diamond beneath the mask. The lattice planes in contrast are inclined with respect to the lattice planes beneath the mask away from the openings over the mask 113. In the on-axis case (a), the inclination is symmetrical on both sides of the opening 114. This can be recognized by two symmetrical peaks in the associated rocking curve. In the off-axis case (b), the masks are preferably overgrown from one side and an asymmetry arises in the rocking curve.

What is claimed is:

1. A method for producing diamond layers, wherein diamond is first grown in a first growth step onto a growth surface of an off-axis heterosubstrate or a off-axis heterosubstrate such that a texture width, in particular a polar and/or azimuthal texture width, of a diamond layer arising through the growing on reduces with an increasing distance from the substrate and then, in a second growth step, diamond is grown on so that the texture width of the diamond layer remains substantially constant with a further increasing spacing from the substrate, wherein networkplanes or network planes of the substrate being inclined by an angle greater than zero with respect to the growth surface.

2. A method for producing diamond layers, wherein diamond is grown onto a growth surface of an off-axis heterosubstrate or a off-axis heterosubstrate; wherein the heterosubstrate has an iridium layer on an off-axis buffer layer, on a preferably monocrystalline silicon substrate; and wherein network planes of the iridium layer are inclined by an angle larger than zero with respect to the growth surface.

3. The method in accordance with claim 2, wherein the buffer layer is or has an oxide buffer layer, preferably yttria-stabilized zirconia (YSZ), with the heterosubstrates resulting therefrom of Ir/YSZ/Si or Ir/YSZ/Si, and/or SrTiO₃, CeO₂, MgO, Al₂O₃, TiO₂, and/or is or has a buffer layer with/from TiN or SiC.

4. The method in accordance with claim 1, wherein the substrate comprises or consists of an iridium layer with off-axis orientation or off-axis orientation, arranged on an off-axis buffer layer, arranged on a preferably monocrystalline silicon substrate, with the crystal planes or crystal planes of the iridium being inclined by the angle.

5. The method in accordance with claim 4, wherein the buffer layer is or has an oxide buffer layer, preferably yttria-stabilized zirconia (YSZ), with the heterosubstrates resulting therefrom of Ir/YSZ/Si or Ir/YSZ/Si, and/or SrTiO₃, CeO₂, MgO, Al₂O₃, TiO₂, and/or is or has a buffer layer with/from TiN or SiC.

6. The method in accordance with wherein the diamond is deposited in the first and/or second growth steps by means of chemical vapor deposition, preferably be means of microwave-assisted chemical vapor deposition, with preferably a nitrogen concentration in a gas used for the chemical vapor deposition in the second growth step being equal to zero or being larger than in the first growth step, preferably ≧400 ppm, particularly preferably ≧800 ppm, particularly preferably ≧1000 ppm, particularly preferably ≧1200 ppm, particularly preferably ≧1500 ppm and/or ≦20000 ppm, preferably ≦10000 ppm, particularly preferably ≦5000 ppm.

7. The method in accordance with- one of the preceding claim 1, characterized in that wherein the angle by which the crystal planes are inclined is ≧2°, preferably ≧4° and/or ≦15°, preferably ≦10°, preferably 8°.

8. The method in accordance with claim 1, wherein the constant polar texture width produced in the second growth step is preferably ≧0.1° particularly preferably ≧0.2°, further preferably ≧0.3°, particularly preferably ≧0.4° and/or ≦2°, preferably ≦1°, particularly preferably ≦0.8°, particularly preferably ≦0.6°, particularly preferably ≦0.5° or that the polar and/or azimuthal texture widths is/are ≦0.1°, preferably ≦0.05°, particularly preferably ≦0.02°

9. The method in accordance with claim 1, wherein diamond is deposited up to a layer thickness of ≧0.5 mm, preferably ≧1 mm, particularly preferably ≧2 mm, particularly preferably ≧4 mm.

10. The method in accordance with claim 1, wherein subsequent to the growth steps diamond is epitaxially grown on the previously grown on layer such that it is subjected to compressive stress with respect to the previously grown on layer.

11. The method in accordance with claim 10, wherein the diamond subjected to compressive stress is grown on at a lower temperature than the previously grown on layer, preferably at a temperature ≦900° C. for off-axis layers or preferably ≦700° C. for of-axis layers and/or is deposited at a higher pressure than the previously grown on layer, preferably at a pressure ≧100 mbar, preferably ≧150 mbar, further preferably ≧200 mbar, and/or ≦500 mbar, preferably ≦400 mbar.

12. The method in accordance with claim 1, wherein at least one mask, in particular a strip mask, is arranged on the substrate and/or on the already deposited diamond before or during the growing on of the diamond such that it extends parallel to the substrate, with the mask having at least one opening through which further diamond can be deposited on the already deposited diamond or on the substrate; and in that after the arrangement of the mask further diamond is deposited over the openings and subsequently, preferably by lateral growth, over the mask so that a closed diamond layer results over the mask.

13. The method in accordance with claim 12, wherein a ratio of width of the openings to a spacing of the margins of two adjacent openings bounding the opening in the same direction is preferably ≦0.5, preferably ≦0.2, further preferably ≦0.1, further preferably ≦0.05, further preferably ≦0.02; and/or in that the width of the openings is ≧1 μm, preferably ≧5 μm and/or ≦20 μm, preferably ≦5 μm.

14. The method in accordance with claim 12, wherein the mask comprises or consists of one or more substances selected from iridium, SiO₂, Ti, Rh, Pt, Cu and/or Ni and/or has a thickness of ≧10 nm, preferably ≧50 nm and/or ≦20 nm, particularly preferably ≦100 nm.

15. A diamond crystal which has dislocation lines which have a preferred orientation, with the main area of the preferred orientation having an angle of >8°, preferably >10°, preferably >15°, particularly preferably >20° with respect to all <001> and <111> crystal directions of the diamond crystal.

16. A diamond crystal which has a thickness >1 mm, preferably >2 mm, particularly preferably >3 mm and/or has an area >5 cm², preferably >10 cm², particularly preferably 30 cm², particularly preferably >50 cm², particularly preferably >70 cm² and/or preferably has a polar texture width of ≧0.05°, preferably ≧0.1°, further preferably ≧0.3°, further preferably ≧0.4° and/or ≦2°, preferably ≦1°, particularly preferably ≦0.8°, further preferably ≦0.6°, further preferably ≦0.5°.

17. A diamond crystal having a breaking strength at a reference thickness of 300 μm of the crystal >1 GPa, preferably >2 GPa, particularly preferably >2.8 GPa, particularly preferably >3 GPa, particularly preferably >3.5 GPa, particularly preferably >3.9 GPa.

18. The diamond crystal, optionally in accordance with claim 15, having a polar and/or azimuthal texture width ≦0.1°, preferably >0.05°, particularly preferably ≦0.02°.

19. The diamond crystal in accordance with claim 15, wherein the diamond crystal is produced heteroepitaxially, preferably with a dislocation density of ≧10⁶ cm⁻², and/or 10⁸ cm⁻²in the case of a texture width of <0.1° or of ≧10⁸ cm⁻² and/or ≦10¹¹ cm⁻²in the case of a texture width of >0.1°.

20. The diamond crystal in accordance with claim 15, wherein the diamond crystal is produced.

21. The diamond crystal in accordance with claim 15, wherein the diamond crystal has at least one epitaxial layer subjected to compressive stress having a compressive stress of ≦−0.5 GPa, preferably ≦−1 GPa and/or ≧−10 GPa, preferably ≧−5 GPa and/or a thickness of ≧0.5 μm, preferably ≧1 μm and/or ≦10 preferably ≦5 μm.

22. A diamond mosaic crystal or a stack of diamond crystals, wherein the diamond mosaic crystal or the stack of diamond crystals is composed of mosaic crystals which are diamond crystals in accordance with claim 15.

23. The diamond mosaic crystal or a stack of diamond crystals in accordance claim 22 whose neutron reflectivity in the wavelength range from 0.05 nm to 0.3 nm with the same mosaic width lies at least at a wavelength above the neutron reflectivity of mosaic crystals or stacks of mosaic crystals based on copper, silicon or germanium.

24. A neutron monochromator having a diamond crystal in accordance with claim 15.

25. A use of a diamond crystal in accordance with claim 15 as an optical window, as a mechanical cutting edge, as a wire draw plate, as a scalpel, as a template for producing diamond layers having an identical texture and inner structure by homoepitaxial growth and subsequent peeling off and/or as an epitaxial growth substrate for other functional layers, preferably nitrides such as AlN, GaN and c-BN.
